(19) United States
(12) Patent Application Publication
(10) Pub. No.: US 2003/0198756 A1
(43) Pub. Date: Oct. 23, 2003

(54) Method for working a parting agent layer applied to a substrate material

(75) Inventors: Juergen Weisser, Jena (DE); Norbert Preuss, Jena (DE)

Correspondence Address: Gerald H. Kiel, Esq., REED SMITH LLP, 599 Lexington Avenue, New York, NY, 10022-7650, US

(73) Assignee: JENOPTIK Automatisierungstechnik GmbH

(21) Appl. No.: 10/419,015

(22) Filed: Apr. 17, 2003

(30) Foreign Application Priority Data
Apr. 18, 2002 (DE) 102 17 725.2

(51) Int. Cl. C23C 14/30; C03C 25/68

(52) U.S. Cl. 427/596; 216/65

(57) ABSTRACT

A method for working a parting agent layer applied to a substrate material, in which the parting agent layer is acted upon by the radiation energy of a TEA CO₂ laser, so that the parting agent layer is heated at least partly to above the destruction temperature of the parting agent and the parting agent therefore loses its parting properties. The substrate material can be particularly a glass forming a vehicle window or a glass powder coat or rubber applied to a window.

### CROSS-REFERENCE TO RELATED APPLICATIONS

This application claims priority of German Application No. 102 17 725.2, filed Apr. 18, 2002, the complete disclosure of which is hereby incorporated by reference.

### BACKGROUND OF THE INVENTION

a) Field of the Invention

The present invention relates to a method for working a parting agent layer applied to a substrate material.

b) Description of the Related Art

In connection with the development of new methods for stripping paint from aircraft, intensive investigations concerning the suitability of different lasers were carried out as is published in the article “Laserentlackung—Stand der Entwicklung [Current Developments in Laser Paint Stripping]”, JOT Journal für Oberflächentechnik, 1997. Apart from the possibility of stripping all aviation materials, there has been a demand for the option of selective removal of individual paint layers. In this connection, it was noted that the sensitive substrate materials made it necessary to minimize thermal loading so as to prevent any damage thereto.

As was reported in this article, pulsed lasers with high pulse outputs and maximum beam geometry formed possible solutions for overcoming this problem. The copper vapor laser, TEA CO₂ laser, Nd:YAG-laser and excimer laser are cited here as examples. It is primarily the absorption through the paint and the penetration depth of the radiation, depending on the emitted wavelength, that determine which laser is particularly suited to the specific stripping application.

The removal of paint by means of a short-pulse laser was discussed in three approaches as thermal, chemical and mechanical process. As investigations have shown, the deposition of radiation energy, particularly in the long-wave electromagnetic range, is carried out thermally. Initially, the direct interaction (absorption) between the laser radiation and the material being worked is predominant. The energy transfer from electromagnetic radiation energy to thermal energy leads to the actual evaporation process which represents the primary ablating mechanism. The evaporated material is subjected to additional heating through the laser pulse in connection with an ionization (plasma formation). Along with the phenomenon of the forces connected with the formation of shock waves and pressure waves in the material being worked, a removal of material through mechanical reinforcement is also observed. As the radiation energy is coupled into the paint, the paint is covered by a pressure wave. Most of this pressure wave is transmitted into the substrate material and undergoes a reflection on the rear side in the form of tensile loading at the substrate material/air interface or boundary layer. When the reflected wave strikes the substrate material/paint boundary layer, a tensile stress which reinforces ablation is brought about at the boundary surface. Further, the article discusses the possibilities of process control and a paint stripping installation, developed by Dornier, with a TEA CO₂ radiation source which leads through a succession of individual scan fields to a structural component part which is stripped of paint over a large surface area and has a high-quality surface. Different application possibilities are presented, all of which lead to a precise ablation with every pulse with a high resolution. The applications mentioned are in ophthalmology, restoration of paintings, and cleaning of soiled monuments. In addition to the special possibilities of process control which are given by optical and acoustic effects in implementing the method and which make possible a highly accurate ablation control, the advantage of such an ablation process consists particularly in that the surface of the substrate material is not heated due to the extremely short duration of the laser pulses and, therefore, thermal damage to the substrate material can be ruled out.

EP 0 391 113 A2 discloses a method for large-area paint stripping of workpieces, particularly fiber composite materials, in which the surface from which the paint is to be removed is heated so rapidly by an excimer laser that the irradiated paint evaporates faster than absorbed energy diffuses in deeper layers. The use of the occurring optical and acoustic effects for regulating the paint stripping depth is also mentioned as particularly advantageous.

In DE 44 13 158 A1, a device is suggested by which layers of paint or plastic are removed by means of a TEA CO₂ laser. In order to achieve the most uniform possible ablation over the work surface, a laser spot with rectangular geometry and with a box-shaped intensity profile and constant laser energy density is generated.

All of the described solutions have the object of contactless, monitored removal of a layer from a substrate material without thermal loading.

The focus of the set of problems described in the following is completely different, although the same object can seemingly be derived from the prior art solution to the specific set of problems.

### PROBLEM ADDRESSED BY THE INVENTION

Particularly in the automotive supplier industry, rubber lips surrounding the contour of the front and rear windows are made by injection molding. In order to be able to remove the injection mold at the end of the process without damaging the cast rubber lip, the die or tool is wetted with a parting agent before the rubber compound is injected. The parting agent, also called anti-adhesion agent, prevents the occurrence of adhesive forces between two contacting surfaces, in this case, the tool surface and the surface of the rubber lip being formed. When the tool is opened, the parting agent can run onto the window in an uncontrolled manner and can form a film or layer of parting agent of varying thickness and width next to and on the rubber lip.

In order to be able to apply a glue in the area of the parting agent layer, for example, for the purpose of gluing the window into the body or for gluing on an ornamental strip, this parting agent layer is currently removed mechanically by hand. Automation is made difficult by the three-dimensional shape of the window, by the varying width and thickness of the parting agent layer, wherein the width and/or thickness can also be zero in some areas, and by the different substrate which can be rubber, uncoated transparent glass, or glass coated with a dark glass powder.

### OBJECT AND SUMMARY OF THE INVENTION

It is the primary object of the invention to provide a method for contactless working of a partial surface on a surface of a substrate material provided with a parting agent layer, so that a glue can adhere to this partial surface. In this connection, the partial surface can be on the surface of different substrate materials such as rubber, glass and/or a tinting glass powder coat. Further, the method should also be applicable when the thickness of the parting agent layer is not uniform.

Insofar as the partial surface being worked is on the rubber lip or the glass powder coat, the gluing surface should advantageously be visible after working.

The method is suitable for mass production and can be carried out quickly and in a fully automated manner.

It is likewise the object of the invention to provide a device by which the method according to the invention can be carried out with a typical three-dimensional front window or rear window.

The object of the invention is met for a method for working a parting agent layer applied to a substrate material in that the parting agent layer is acted upon by the radiation energy of a TEA CO₂ laser, so that the parting agent layer is heated at least partially above the temperature at which the parting agent is destroyed and the parting agent accordingly loses its parting properties.

Underlying the invention is the understanding that it is not necessary to remove the parting agent layer from the surface of the substrate material in order for the applied glue to adhere well; rather, it is sufficient to cancel the function of the parting agent layer. This is possible by means of local heating to a temperature above the temperature at which the parting agent is destroyed. For many parting agents, the destruction temperature is only about 80°. A TEA CO₂ laser is used for fast and local heating limited to the partial surface provided for the glue.

The invention will be described more fully in the following with reference to an embodiment example shown in the drawings.

### BRIEF DESCRIPTION OF THE DRAWINGS

In the drawings:

FIG. 1a shows a front window with a track on glass;

FIG. 1b shows an enlarged section from FIG. 1a;

FIG. 1c shows an energy diagram with slight overlapping of the surface elements;

FIG. 2a shows a rear window with a track on glass and a track on rubber;

FIG. 2b shows an enlarged section from FIG. 2a; and

FIG. 2c shows an energy diagram with slight overlapping of the surface elements.

### DESCRIPTION OF THE PREFERRED EMBODIMENTS

The operation of a TEA CO₂ laser was thoroughly explained in the description of the prior art. The plasma formation is particularly relevant to the method described in the following. There is no need to regulate the ablation depth because the ablation only occurs here as a secondary effect.

Assuming that the method according to the invention is particularly suited to the working of vehicle windows and that the vehicle windows are flat, but usually slightly curved and are at least shaped like a rectangle in the broadest sense, the partial surface to be worked, hereinafter referred to as the track, is generally a rectangle-like annular surface or portions thereof.

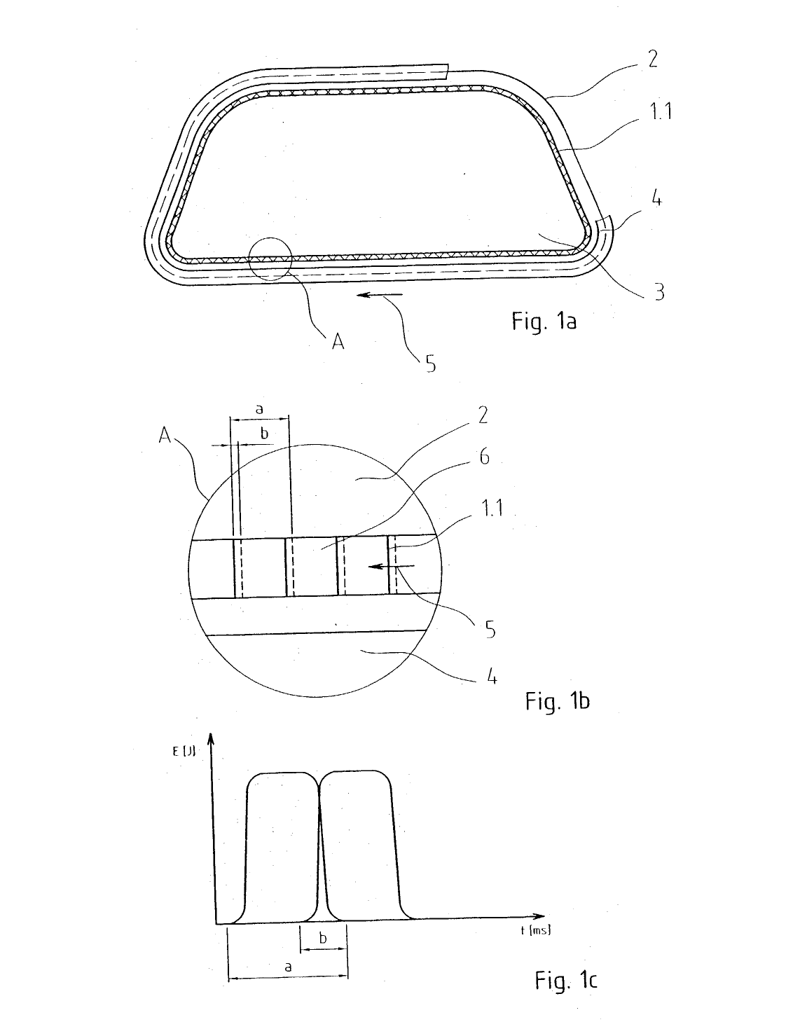

The implementation of the method will be described with reference to the working of a front window illustrated in FIGS. 1a-1c. The outer contour 2 of the window 3 determines the geometry of the track 1.1 to be worked. A strip-shaped track 1.1 is worked alongside the rubber lip 4 parallel to the outer contour 2 enclosed by the surrounding rubber lip 4 in order to fix the window 3 in the body of the vehicle subsequently by means of a glue applied to this track 1.1. The strip-shaped track 1.1 forming a closed ring has a width of 18 mm, for example. The parting agent layer in the area of the track 1.1 can vary in thickness from 0 to about 100 μm. The substrate material is uncoated glass in the embodiment example shown in FIG. 1.

In order to work the track 1.1, the beam of a pulsed TEA CO₂ laser is directed to the window 3 with a square beam outlet of 18 mm×18 mm, a maximum pulse energy of 6.5 J, and a maximum pulse frequency of 50 Hz.

Corresponding to the impinging laser spot with an edge length a of 18 mm×18 mm, the track 1.1 comprises a plurality of surface elements 6 of dimensions 18 mm×18 mm lying next to one another or overlapping in the track direction 5. In principle, every surface element 6 is acted upon by a laser pulse. A slight overlap b (b<a/10) of the edge areas (see FIG. 1b) is advantageous because of the drop in intensity in the edge areas and accordingly serves for a homogeneous energy input along the track 1.1 (see FIG. 1c). The energy input is increased by increasing the overlap b (b>50% a).

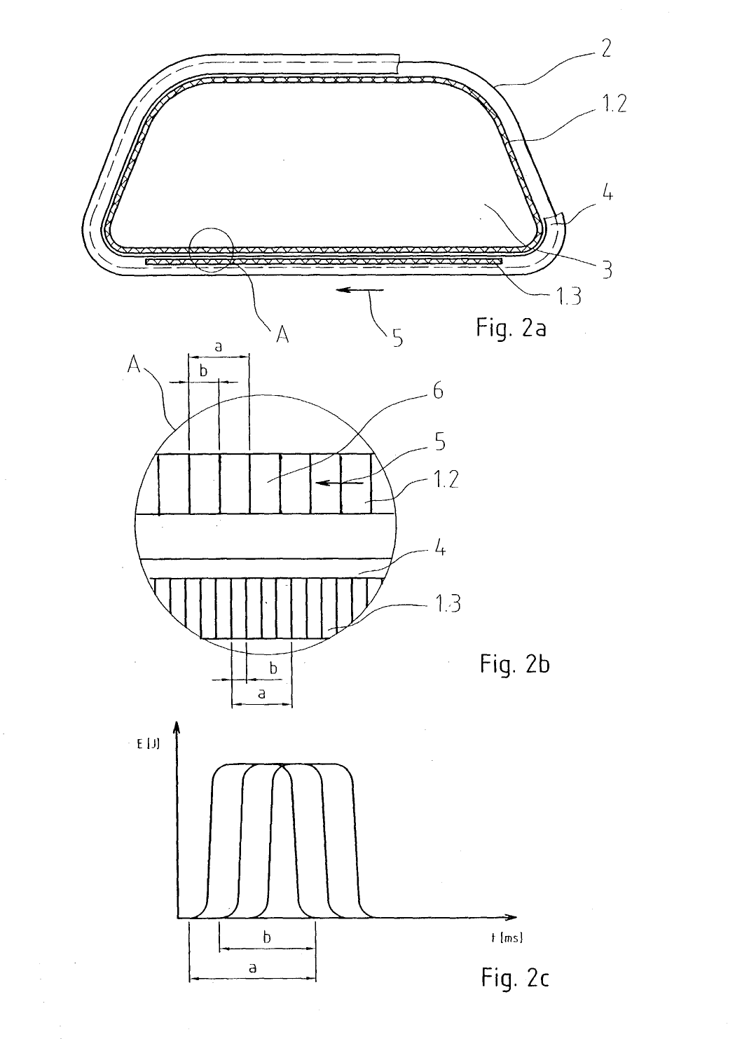

As is shown by way of example in FIG. 2b, the energy input is doubled (b=a/2) for a track 1.2 and tripled (b=2a/3) for a track 1.3 is. Track 1.2 is generated on a glass powder coat and track 1.4 is generated on rubber. An energy diagram for triple energy input is shown in FIG. 2c. The energy input can accordingly be determined in a material-specific manner depending on the substrate material in addition to a regulating of the laser output by the amount of the overlap b. The overlap is determined by way of the pulse frequency of the laser and the speed at which the window 3 is moved in the track direction 5 in relation to the laser spot.

The very high amplitude values of the individual pulse of the TEA CO₂ in the first 100 ns bring about a sudden evaporation of the parting agent layer in an absorption area of approximately 5-10 μm depending on parameter settings. The evaporation products form an absorption cloud which can be penetrated only partially by the subsequent radiation but is mostly absorbed, so that plasma is formed. This plasma in front of the material surface heats the parting agent layer that has not evaporated by heat radiation in a small volume area and accordingly heats the parting agent above its destruction temperature. By destruction temperature is meant the temperature at which the parting agent loses its parting effect. The conduction of heat is negligibly low due to the short irradiation periods during the entire working process.

When the radiation impinges on a location that is free of parting agent, i.e., where the thickness of the parting agent layer is zero, there is an interaction with the substrate material. While the glass must remain undamaged, i.e., the energy input is selected in such a way that no irreversible changes occur in the glass, a visible ablation may be desirable when the substrate material is a sintered on dark glass powder coat or rubber. This can be advantageous for detecting the applied tracks 1.2; 1.3 for the subsequent gluing process or to increase the surface roughness for a better gluing connection. This does not impair function. In order to achieve a more pronounced visual effect, either the laser output can be increased up to the maximum output of the laser of 250 W and/or, as was already mentioned, a greater overlapping of the laser spots defining the surface elements can be carried out. By making the overlap very large, the energy input per surface unit can be multiplied compared to an individual pulse.

However, damage to the glass must be avoided in all cases. This would not only impair the transparency in the adjoining areas around the impinging laser spot, it would also lead to the destruction of the glass surface, which is the same as impairment of function. In this case, the output is as low as possible at around 28 KW.

It was assumed in the examples described above that the laser spot is a square with dimensions 18 mm×18 mm. The square laser spot by which radiation is applied to a square surface element of the tracks 1.1, 1.2 and 1.3 is particularly advantageous for the described application of the method to a front window or rear window. As is shown in FIG. 1a and FIG. 2a, the tracks 1.1 and 1.2 to be worked, strictly speaking, form a trapezoidal ring, i.e., tracks 1.1 and 1.2 are formed by four straight-line strips which together enclose an angle close to, but not equal to, 90°. A linear relative movement of the laser spot of less than or equal to 18 mm is necessary for working the surface elements along the straight lines. Changing direction does not require rotation by the angle enclosed by the two adjoining strips, but only a rotation corresponding to the angular deviation of 90°. Therefore, the method can be carried out faster. Of course, the success of the method according to the invention is dependent on the shape of the generated laser spot. This laser spot can also be rectangular or round, for example, adapted to the shape of the partial surface to be worked.

While the foregoing description and drawings represent the present invention, it will be obvious to those skilled in the art that various changes may be made therein without departing from the true spirit and scope of the present invention.

What is claimed is:

1. A method for working a parting agent layer applied to a substrate material, comprising the steps of:
applying the radiation energy of a TEA CO₂ laser on the parting agent layer so that the parting agent layer is heated at least partly above the destruction temperature of the parting agent and the parting agent therefore loses its parting properties.

2. The method according to claim 1, wherein the substrate material is glass in the form of a window and the TEA CO₂ laser generates a laser spot on the window which produces a track on the window due to the displacement of the window relative to the laser, this track comprising a plurality of surface elements acted upon by the laser spot.

3. The method according to claim 1, wherein the substrate material is a dark glass powder coat on a window and the TEA CO₂ laser generates a laser spot on the glass powder coat which produces a track on the glass powder coat due to the displacement of the window relative to the laser, this track comprising a plurality of surface elements acted upon by the laser spot.

4. The method according to claim 1, wherein the substrate material is rubber which adheres to a window and the TEA CO₂ laser generates a laser spot on the rubber which produces a track on the rubber due to the displacement of the window relative to the laser, this track comprising a plurality of surface elements acted upon by the laser spot.

5. The method according to claim 2, wherein the energy input by the laser beam along the track is selected in such a way that no irreversible changes occur in the substrate material.

6. The method according to claim 3, wherein the energy input by the laser beam along the tracks is selected in such a way that irreversible visible changes occur in the substrate material.

7. The method according to claim 4, wherein the energy input by the laser beam along the tracks is selected in such a way that irreversible visible changes occur in the substrate material.

8. The method according to claim 5, wherein the energy input is determined by the control of the laser output.

9. The method according to claim 6, wherein the energy input is determined by the control of the laser output.

10. The method according to claim 7, wherein the energy input is determined by the control of the laser output.

11. The method according to claim 5, wherein the energy input is determined by the overlap b of the surface elements with an edge length a which is predetermined by the frequency of the laser and the speed at which the substrate material is displaced relative to the laser in a track direction.

12. The method according to claim 6, wherein the energy input is determined by the overlap b of the surface elements with an edge length a which is predetermined by the frequency of the laser and the speed at which the substrate material is displaced relative to the laser in a track direction.

13. The method according to claim 7, wherein the energy input is determined by the overlap b of the surface elements with an edge length a which is predetermined by the frequency of the laser and the speed at which the substrate material is displaced relative to the laser in a track direction.

14. The method according to claim 8, wherein the energy input is determined by the overlap b of the surface elements with an edge length a which is predetermined by the frequency of the laser and the speed at which the substrate material is displaced relative to the laser in a track direction.

15. The method according to claim 9, wherein the energy input is determined by the overlap b of the surface elements with an edge length a which is predetermined by the frequency of the laser and the speed at which the substrate material is displaced relative to the laser in a track direction.

16. The method according to claim 10, wherein the energy input is determined by the overlap b of the surface elements with an edge length a which is predetermined by the frequency of the laser and the speed at which the substrate material is displaced relative to the laser in a track direction.

17. The method according to claim 11, wherein the laser spot is square and has an almost homogeneous energy distribution in both axes.

18. The method according to claim 12, wherein the laser spot is square and has an almost homogeneous energy distribution in both axes.

19. The method according to claim 13, wherein the laser spot is square and has an almost homogeneous energy distribution in both axes.

20. The method according to claim 14, wherein the laser spot is square and has an almost homogeneous energy distribution in both axes.

21. The method according to claim 15, wherein the laser spot is square and has an almost homogeneous energy distribution in both axes.

22. The method according to claim 16, wherein the laser spot is square and has an almost homogeneous energy distribution in both axes.
